(19) United States
(12) Patent Application Publication
(10) Pub. No.: US 2017/0149002 A1
(43) Pub. Date: May 25, 2017

(54) METHOD OF MANUFACTURING ORGANIC THIN FILM TRANSISTOR, ORGANIC THIN FILM TRANSISTOR, AND DEVICE OF TREATING SURFACE OF THIN FILM

(71) Applicant: Samsung Electronics Co., Ltd., Suwon-si (KR)

(72) Inventors: Jiyoung Jung, Seoul (KR); Joo Young Kim, Hwanseong-si (KR); Jeong II Park, Seongnam-si (KR)

(73) Assignee: Samsung Electronics Co., Ltd., Suwon-si (KR)

(21) Appl. No.: 15/267,242

(22) Filed: Sep. 16, 2016

(30) Foreign Application Priority Data
Nov. 20, 2015 (KR) 10-2015-0163235

(51) Int. Cl. H01L 51/05; H01L 51/00

(52) U.S. Cl. CPC H01L 51/0545; H01L 51/0002

(57) ABSTRACT

A method of manufacturing an organic thin film transistor includes forming a gate electrode and a gate insulator on a substrate, forming a self-assembled layer from self-assembled layer precursor on the gate insulator and forming an organic semiconductor on the self-assembled layer, a friction force is applied to the surface of the self-assembled layer in at least two directions between forming the self-assembled layer and forming the organic semiconductor, and an organic thin film transistor manufactured by the method, and a display device including the same are provided. A device of treating a surface of a thin film used for the method is provided.

### CROSS REFERENCE TO RELATED APPLICATIONS

This application claims priority to and the benefit of Korean Patent Application No. 10-2015-0163235, filed in the Korean Intellectual Property Office, on Nov. 20, 2015, the entire contents of which are incorporated herein by reference.

### BACKGROUND

1. Field

Example embodiments relate to an organic thin film transistor, a method of manufacturing the same, and a device of treating a surface of a thin film.

2. Description of the Related Art

A flat panel display (e.g., a liquid crystal display (LCD), an organic light emitting diode (OLED) display, an electrophoretic display, etc.) includes a pair of electric field-generating electrodes and an electrical optical active layer interposed therebetween. The liquid crystal display (LCD) includes a liquid crystal layer as an electric optical active layer, and the organic light emitting diode (OLED) display includes an organic emission layer as an electrical optical active layer.

One of the pair of the electric field-generating electrodes is commonly connected to a switching device and receives an electrical signal, and the electrical optical active layer transforms the electrical signal into an optical signal and thus displays an image.

The flat panel display includes a thin film transistor (TFT) that is a three-terminal element as a switch, a gate line to transfer a scan signal for controlling the thin film transistor, and a data line to transfer signal applied to a pixel electrode.

Research on an organic thin film transistor (OTFT) including an organic semiconductor instead of an inorganic semiconductor, e.g., a silicon (Si) semiconductor, as one type of thin film transistor is actively being conducted.

The organic thin film transistor may be made into a fiber or a film due to characteristics of an organic material, and thus is drawing attention as a core element for a flexible display device.

In order to improve array of the organic semiconductor in the organic thin film transistor, a self-assembled layer may be formed on the surface of an insulator. Herein, planarity of the self-assembled layer on the surface of the insulator plays a critical role of determining charge transport characteristics of the organic thin film transistor.

### SUMMARY

Example embodiments provide an organic thin film transistor device having increased charge transport characteristics by removing multilayers and particles present in a self-assembled layer formed on the surface of an insulator and/or an electrode using a mechanical cleaning method and improving planarity of the self-assembled layer.

According to example embodiments, a method of manufacturing an organic thin film transistor includes forming a gate electrode and a gate insulator on a substrate, forming a self-assembled layer on the gate insulator from a self-assembled layer precursor, applying friction to a surface of the self-assembled layer in at least two directions, and forming an organic semiconductor on the self-assembled layer.

The friction may be applied by rubbing the surface of the self-assembled layer in the at least two directions.

The friction force may be applied by rubbing a plate, a drum, or a combination thereof with the surface of the self-assembled layer.

The friction may be applied by rotating a plate having a rotation axis substantially perpendicular to the substrate, a drum having a rotation axis substantially parallel to the substrate, or a combination thereof.

The rotation may be performed at a speed of less than or equal to about 2,000 rpm.

At least one side of the plate and a surface of the drum may include a region where cloth is applied.

The friction may be applied through movement of the substrate having the self-assembled layer in a horizontal direction.

The friction may be simultaneously applied to a region of the surface of the self-assembled layer.

The self-assembled layer may be formed by dipping, depositing, or spin coating.

The self-assembled layer may be formed directly on the gate insulator.

The self-assembled layer may be formed from the self-assembled layer precursor including a compound represented by Chemical Formula 1.

X—Y—Z [Chemical Formula 1]

In Chemical Formula 1,

X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein each of X₁, X₂, and X₃ are independently hydrogen, a substituted or unsubstituted C₁ to C₂₀ alkoxy group, a hydroxy group, or a halogen,

Y is —(CH₂)n- (n is an integer of 0 to 30), —(CF₂)m- (m is an integer of 0 to 30), or a combination thereof, and

Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, a halogen, thiol group, amine group, a nitro group or a combination thereof.

A liquid material may be coated on the surface of the self-assembled layer after forming the self-assembled layer and prior to applying friction.

The liquid material may include hexane, cyclohexane, chloroform, anisole, mesitylene, xylene, toluene, ketone, ether, acetate, alcohol, amide, or a combination thereof.

The method may further include treating the coated self-assembled layer with heat, a sound wave, acid, base, or a combination thereof after forming the self-assembled layer and prior to coating the liquid material.

The coated self-assembled layer may be treated with the sound wave treatment while the coated self-assembled layer is dipped in a homogeneous or heterogeneous liquid material.

According to example embodiments, a device for treating a surface of a thin film includes a rotator having a substantially perpendicular or parallel rotation axis with a ground surface, the rotator being configured to rotate on the surface of the thin film and apply friction in at least two directions thereon.

According to example embodiments, an organic thin film transistor is manufactured using the method of example embodiments.

According to example embodiments, a display device includes the organic thin film transistor of example embodiments.

### BRIEF DESCRIPTION OF THE DRAWINGS

FIG. 1 is a cross-sectional view showing an organic thin film transistor according to example embodiments,

FIG. 2 is a cross-sectional view showing an organic thin film transistor according to example embodiments,

FIGS. 3 to 5 are cross-sectional views sequentially showing a method of manufacturing the thin film transistor of FIG. 1,

FIG. 6 is a schematic view showing one application example of a friction force to the surface of the self-assembled layer,

FIG. 7 is a schematic view showing another application example of a friction force to the surface of the self-assembled layer,

FIG. 8 is a graph showing charge mobility of the organic thin film transistor according to Example 1,

FIG. 9 is a graph showing charge mobility of the organic thin film transistor according to Example 2,

FIG. 10 is a graph showing charge mobility of the organic thin film transistor according to Comparative Example 1,

FIG. 11 shows an atomic force microscope (AFM) image showing the surface of the self-assembled layer according to Example 1,

FIG. 12 shows an atomic force microscope (AFM) image showing the surface of the self-assembled layer according to Example 2,

FIG. 13 shows an atomic force microscope (AFM) image showing the surface of the self-assembled layer according to Comparative Example 1,

FIG. 14 shows an atomic force microscope (AFM) image showing the surface of the organic semiconductor according to Example 1,

FIG. 15 shows an atomic force microscope (AFM) image showing the surface of the organic semiconductor according to Example 2, and

FIG. 16 shows an atomic force microscope (AFM) image showing the surface of the organic semiconductor according to Comparative Example 1.

### DETAILED DESCRIPTION

The present disclosure will be described more fully hereinafter with reference to the accompanying drawings, in which example embodiments of this disclosure are shown. However, this disclosure may be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It should be understood that, although the terms first, second, third, etc. may be used herein to describe various elements, components, regions, layers and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a thin film transistor according to example embodiments is illustrated.

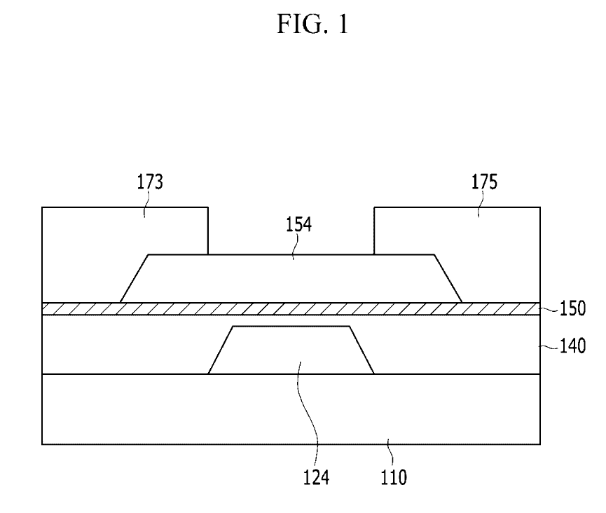

FIG. 1 is a cross-sectional view showing an organic thin film transistor according to example embodiments.

A gate electrode 124 is formed on a substrate 110 made of transparent glass, silicon or plastic.

The gate electrode 124 is connected with a gate line (not shown) for transferring a gate signal.

A gate insulator 140 is formed on the gate electrode 124.

The gate insulating layer 140 may be made of an organic material or an inorganic material, examples of the organic material may include a polyvinyl alcohol-based compound, a polyimide-based compound, a polyacryl-based compound, a polystyrene-based compound, and a dissoluble polymer compound such as benzocyclobutane (BCB), and examples of the inorganic material may include a silicon nitride (SiNₓ) and a silicon oxide (SiOₓ), and may be a single layer or a stack layer of two or more.

A self-assembled layer 150 is formed on the gate insulator 140.

The self-assembled layer 150 may be made of, for example, a self-assembled monolayer precursor having one end or both ends with affinity for an insulator.

The precursor of the self-assembled monolayer 150 may include, for example, a compound represented by Chemical Formula 1.

X—Y—Z [Chemical Formula 1]

In Chemical Formula 1,

X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein each of X₁, X₂, and X₃ are independently hydrogen, a substituted or unsubstituted C₁ to C₂₀ alkoxy group, a hydroxy group, or a halogen,

Y is —(CH₂)n- (n is an integer of 0 to 30), —(CF₂)m- (m is an integer of 0 to 30), or a combination thereof, and

Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, halogen, a thiol group, amine group, a nitro group or a combination thereof.

For example, the precursor of the self-assembled layer 150 may be compounds of Group 1 but is not limited thereto.

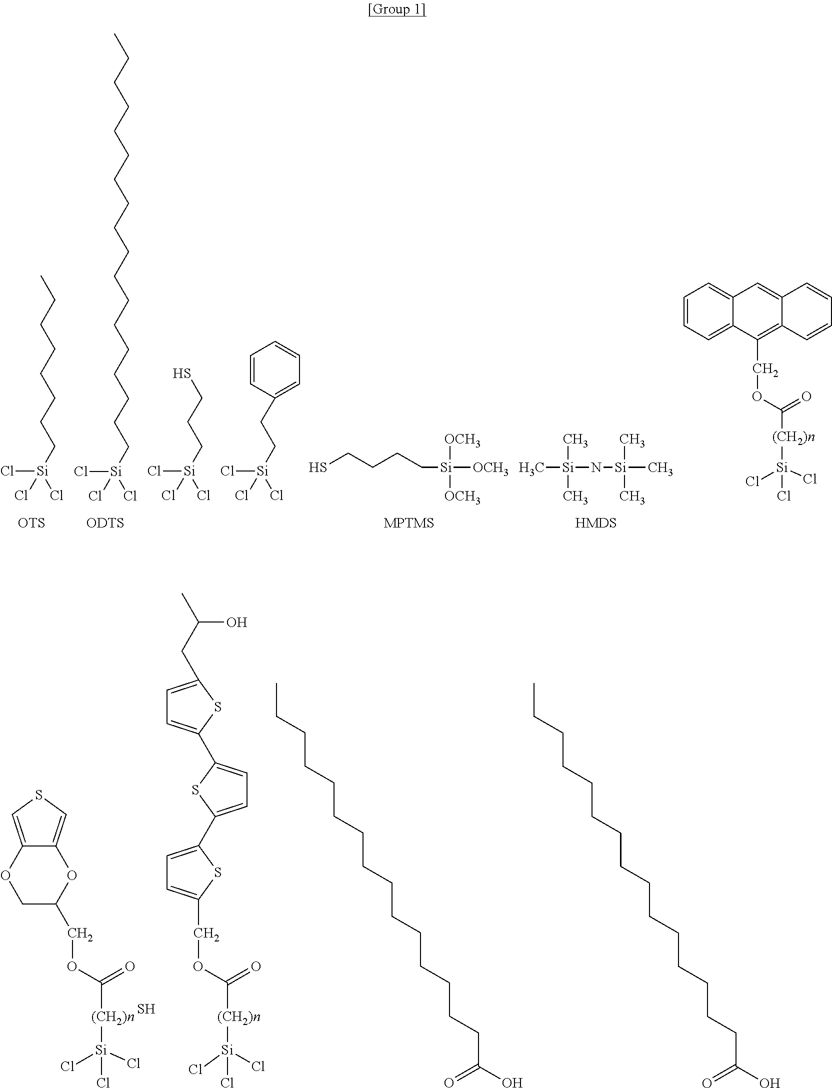

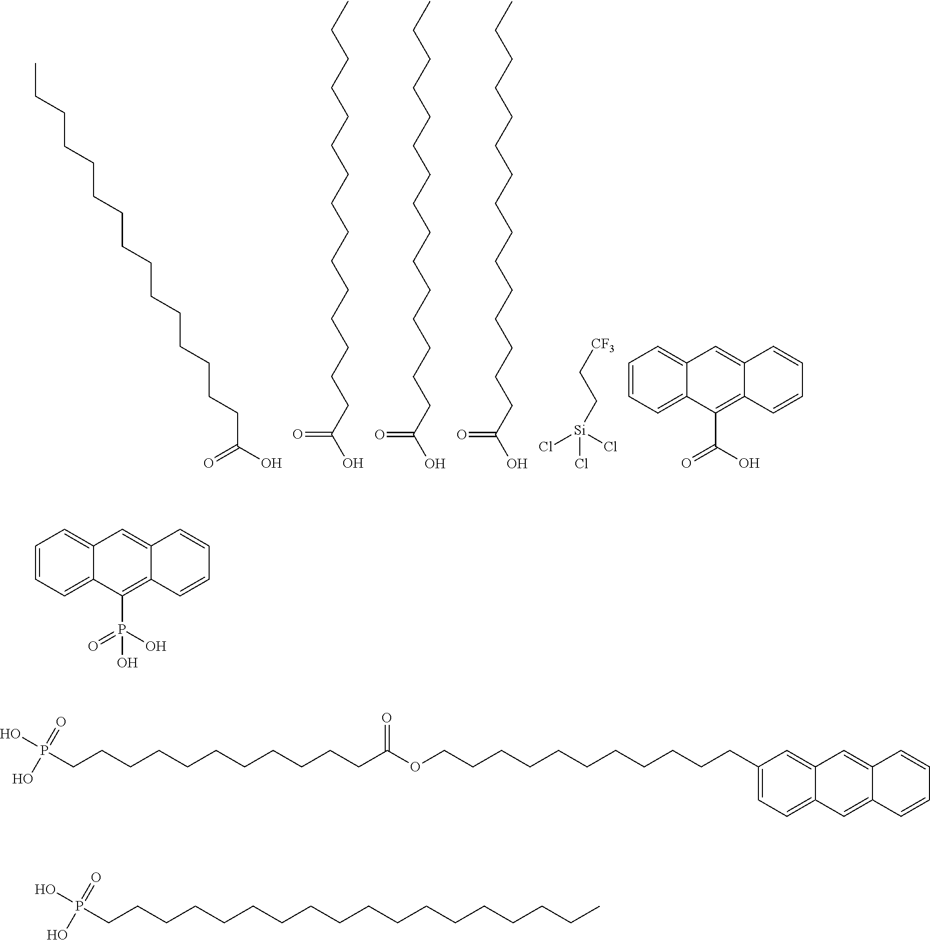

On the other hand, an organic semiconductor 154 is formed on the gate insulator 140 and the self-assembled layer 150.

The organic semiconductor 154 may be made of at least one selected from pentacene and a precursor thereof, tetrabenzoporphyrin and a precursor thereof, polyphenylenevinylene and a precursor thereof, polyfluorene and a precursor thereof, polythienylenevinylene and a precursor thereof, polythiophene and a precursor thereof, polythienothiophene and a precursor thereof, polyarylamine and a precursor thereof, phthalocyanine and a precursor thereof, metallized phthalocyanine or a halogenated derivative thereof, perylenetetracarboxylic dianhydride (PTCDA), naphthalenetetracarboxylic dianhydride (NTCDA) or an imide derivative thereof, perylene or coronene, and a substituent-containing derivatives thereof.

The self-assembled layer 150 is formed between the organic semiconductor 154 and the gate insulator 140 and may improve molecular array of an organic semiconductor material and thus reduce defects in a region where a channel of a thin film transistor is formed and improve charge mobility of the thin film transistor.

A source electrode 173 and a drain electrode 175 are formed on the self-assembled layer 150.

The source electrode 173 and the drain electrode 175 face each other in a center of the gate electrode 124. The source electrode 173 is electrically connected with a data line (not shown) for transferring a data signal.

The source electrode 173 and the drain electrode 175 may include at least one metal selected from gold (Au), copper (Cu), nickel (Ni), silver (Ag), aluminum (Al), molybdenum (Mo), chromium (Cr), tantalum (Ta), and titanium (Ti), or an alloy thereof.

FIG. 1 shows a thin film transistor having an upper contact (a top contact) structure as one example of a thin film transistor, but the present disclosure is not limited thereto and may be applied to a thin film transistor having all the structures including a bottom contact structure.

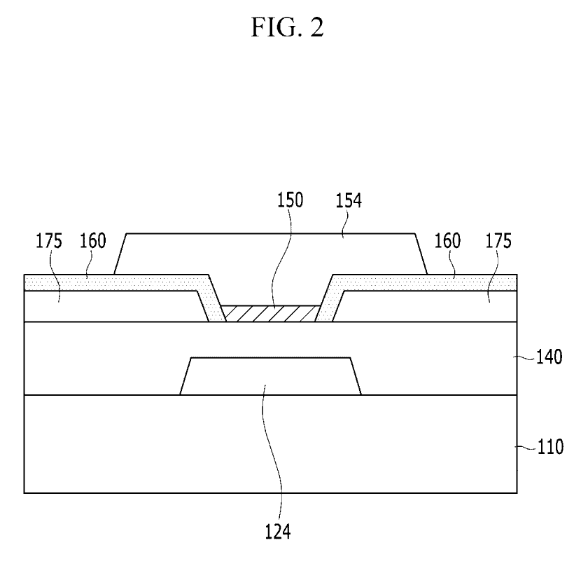

FIG. 2 is a cross-sectional view showing an organic thin film transistor according to example embodiments. The organic thin film transistor shown in FIG. 2 has a bottom contact structure.

For example, as shown in FIG. 1, the self-assembled layer 150 may be formed directly on the gate insulator 140, but according to example embodiments, as shown in FIG. 2, the self-assembled layers 150 and 160 may be formed directly on the gate insulator 140 and/or directly on the source electrode 173 and the drain electrode 175. Referring to FIG. 2, the self-assembled layer 150 formed between the organic semiconductor 154 and gate insulator 140 may improve molecular array of an organic semiconductor material and thus reduce defects in a region where a channel of a thin film transistor is formed and improve charge mobility, and the self-assembled layer 160 between the organic semiconductor 154 and the source electrode 173 and between the organic semiconductor 154 and the drain electrode 175 plays a role of a charge injection layer and decreases contact resistance therebetween and increases charge mobility.

The precursor of the self-assembled layer 160 may include, for example, a thiol-based compound, a thioacetyl-based compound, a disulfide-based compound, or a combination thereof.

For example, the precursor of the self-assembled layer 160 may be compounds of Group 2, but is not limited thereto.

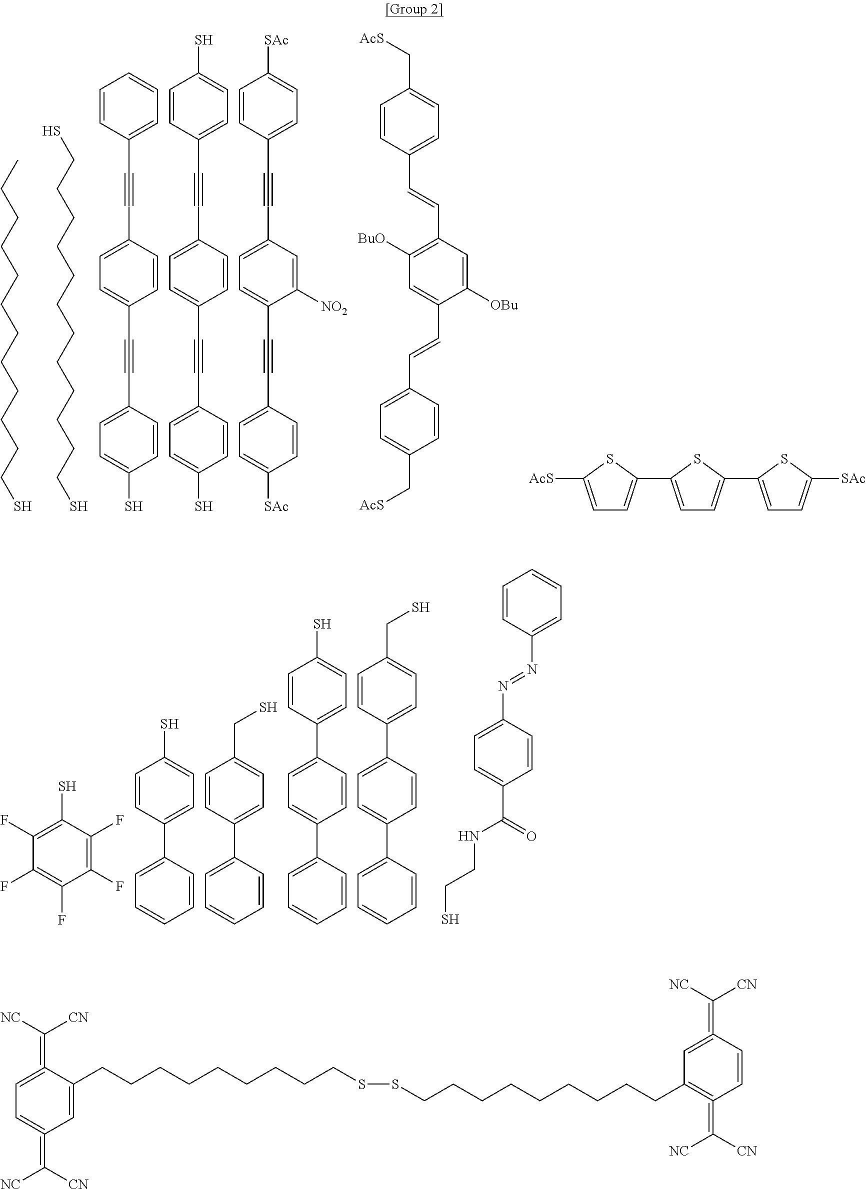

The precursor of the self-assembled layer 160 may include, for example a fluorine-containing thiol-based compound such as pentafluorobenzenethiol shown in Group 2.

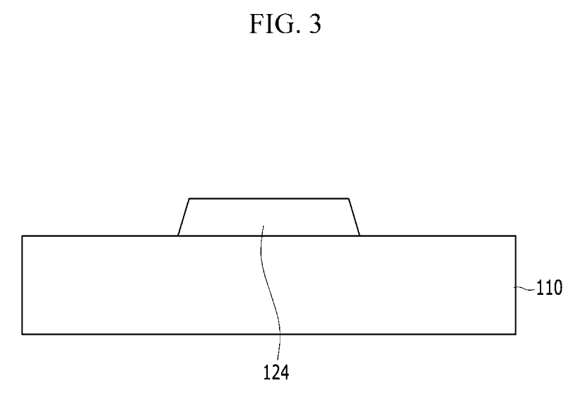

Hereinafter, a method of manufacturing an organic thin film transistor is illustrated referring to FIGS. 3 to 5 along with FIG. 1.

FIGS. 3 to 5 are cross-sectional views sequentially showing a method of manufacturing the thin film transistor of FIG. 1.

Referring to FIG. 3, the gate electrode 124 is formed by forming a conductive layer on the substrate 110 through sputtering and performing photolithography.

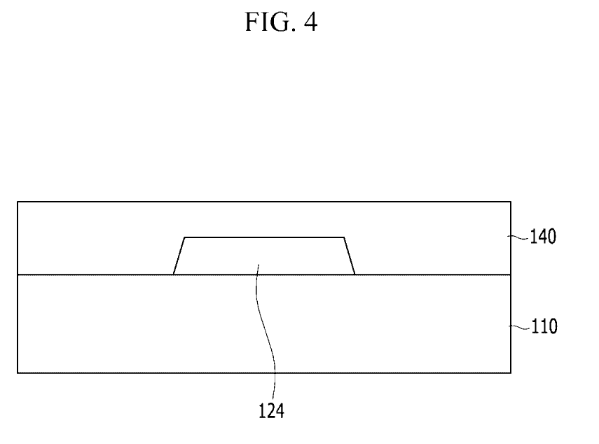

Referring to FIG. 4, the gate insulating layer 140 is formed on the gate electrode 124. The gate insulating layer 140 may be formed, for example, in a dry process such as chemical vapor deposition, or in a solution process such as spin coating, inkjet printing, and the like.

Subsequently, a self-assembled layer 150 is formed on the gate insulator 140.

Before forming the self-assembled layer 150, the surface of the gate insulator 140 may be pre-treated. The pre-treatment is performed to activate the surface of the gate insulator 140 and thus easily react it with the precursors of the post-described self-assembled layer 150. The pretreatment may be omitted. The pretreatment may be performed by treating the gate insulator 140 with oxygen plasma or UV-ozone.

The self-assembled layer 150 may be, for example, formed by dipping, depositing, or spin coating. The self-assembled layer 150 may be, for example formed by a solution process. A solvent for the solution process may be, for example an aliphatic hydrocarbon solvent such as hexane; an aromatic hydrocarbon solvent such as anisole, mesitylene, and xylene; a ketone based solvent such as methylisobutylketone, 1-methyl-2-pyrrolidinone, and acetone; an ether based solvent such as cyclohexanone, tetrahydrofuran, and isopropylether; an acetate based solvent such as ethylacetate, butylacetate, and propylene glycolmethyletheracetate; an alcohol based solvent such as isopropyl alcohol, and butanol; an amide based solvent such as dimethyl acetamide, and dimethyl formamide; a silicon-based solvent; or a combination thereof, but is not limited thereto.

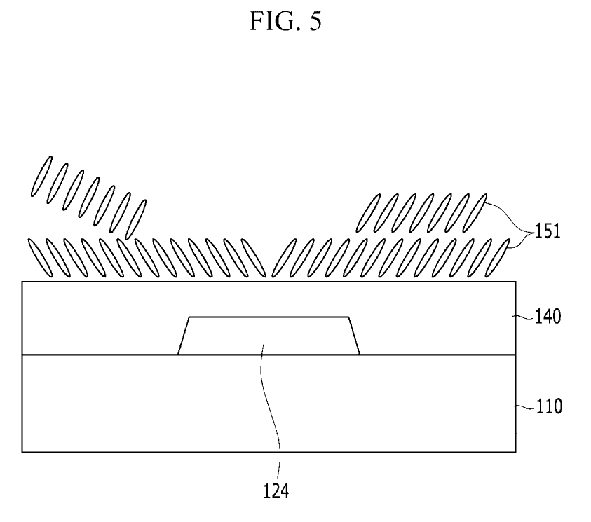

Referring to FIG. 5, when self-assembled layer precursors 151 are supplied on the gate insulator 140, the self-assembled layer precursors 151 are self-arranged on the gate insulator 140.

However, as shown in FIG. 5, the self-assembled layer precursors 151 may not form a single layer but a multilayer or be present as a particle. The reason is that reactivity between the gate insulator 140 and the self-assembled layer precursors 151 is similar to reactivity among the self-assembled layer precursors 151 and thus cause a polymerization reaction among the self-assembled layer precursors 151. The particle may be for example formed through a reaction among moieties of the self-assembled layer precursors 151. The particle or multilayer formed on the surface of the gate insulator 140 may increase roughness of the gate insulator 140 and resultantly, deteriorate reliability of an organic thin film transistor device.

According to example embodiments, a method of manufacturing an organic thin film transistor may include performing a predetermined treatment on the surface of the self-assembled layer 150 formed from the self-assembled layer precursors 151.

The surface treatment may be to apply a friction force on the surface of the self-assembled layer 150 after forming the self-assembled layer 150 but before forming the organic semiconductor 154. The friction force may be applied in a random direction, at least two directions.

Accordingly, the particle or multilayer attached on the surface of the self-assembled layer 150 may be efficiently removed, and resultantly, planarity of the thin film may be improved. Accordingly, the array of the organic semiconductor 154 is increased, and the grain size of the semiconductor is increased, and resultantly, reliability of an organic thin film transistor may be improved.

For example, application of the friction force may include rubbing the surface of the self-assembled layer 150 in at least two directions. For example, application of the friction force may include rubbing the surface of the self-assembled layer 150 with a plate, a drum, or a combination thereof. Herein, the plate has a predetermined thickness, but the thickness or the area of the plate have no particular limit. In addition, the drum may have a three dimensional cylinder shape, but the cylinder has no particular limit about a length or a width.

The friction may be performed by rotating a plate having a substantially vertical rotation axis with the substrate 110 on the surface of the self-assembled layer 150 according to example embodiments or a drum having a substantially parallel rotation axis with the substrate 110 on the surface of the self-assembled layer 150 according to example embodiments. Instead, the friction of the plate/drum on the surface of the self-assembled layer 150 may be performed by simultaneously moving the substrate 110 in a horizontal direction.

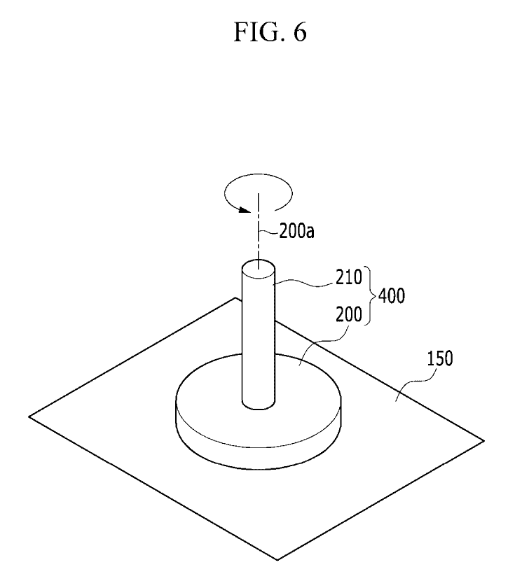

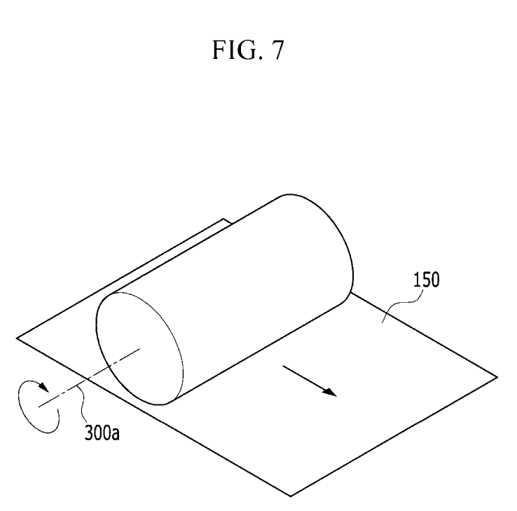

FIG. 6 is a schematic view showing one application example of a friction force to the surface of the self-assembled layer, and FIG. 7 is a schematic view showing another application example of a friction force to the surface of the self-assembled layer.

Referring to FIG. 6, a plate 200 having a substantially vertical rotation axis 200a with a substrate (not shown) having the self-assembled layer 150 is rotated on the self-assembled layer 150 and rubbed with the surface of the self-assembled layer 150. On the plate 200, a rod 210 connected to the plate 200 is positioned, and the rod 210 is rotated to rotate the plate 200 and generates a friction force in a region where the plate contacts with the surface of the self-assembled layer 150. Referring to FIG. 6, the friction force may be simultaneously applied to a region having a predetermined area on the surface of the self-assembled layer 150, that is, a region where the plate 200 contacts with the surface of the self-assembled layer 150 and accordingly, remove a particle over the entire area of the self-assembled layer 150. As shown in FIG. 6, when the plate 200 is rotated, the friction force may be applied on the surface of the self-assembled layer 150 in infinitively many directions.

Referring to FIG. 7, a drum 300 having a substantially parallel rotation axis 300a with a substrate (not shown) having the self-assembled layer 150 is rotated on the self-assembled layer 150 and rubbed with the surface of the self-assembled layer 150. In FIG. 7, when the drum 300 is rotated in a back and forth direction, a friction force may be applied on the surface of the self-assembled layer 150 in at least two directions.

In FIGS. 6 and 7, the plate 200 and the drum 300 may be rotated for example at a speed of less than or equal to about 2,000 rpm but is not limited thereto.

Referring to FIGS. 6 and 7, cloth may be applied to a region where the plate 200 and the drum 300 are rubbed on the surface of the self-assembled layer 150. The cloth has predetermined binding properties with a particle on the surface of the self-assembled layer 150 and thus is bonded with the particle, and resultantly, the particle may be removed from the surface of the self-assembled layer 150. The cloth has no particular limit in terms of a material and may be selected considering properties of the precursor of the self-assembled layer 150.

On the other hand, a step of coating a liquid material on the surface of the self-assembled layer 150 may be performed between forming the self-assembled layer 150 and applying a friction force on the surface of the self-assembled layer 150. The liquid material is applied on the surface of the self-assembled layer 150 and thus may play a role of assisting efficient removal of a particle on the surface of the self-assembled layer 150. The liquid material may include, for example hexane, cyclohexane, chloroform, anisole, mesitylene, xylene, toluene, ketone, ether, acetate, alcohol, amide, or a combination thereof, but is not limited thereto, and may be selected considering properties of the precursor of the self-assembled layer 150. After coating the liquid material on the self-assembled layer 150, a friction force may be applied on the surface of the self-assembled layer 150 before the liquid material is dried.

On the other hand, a step of treating the self-assembled layer 150 with heat, a sound wave, or acid and/or base may be included between forming the self-assembled layer 150 and coating the liquid material. The sound wave treatment may be performed for example for about 1 minute to about 10 minutes in a state that the self-assembled layer 150 is dipped in a homogeneous or heterogeneous liquid material with the liquid material coated on the surface of the self-assembled layer 150. The heat treatment may be performed for example at about 100° C. to about 200° C. for about 10 minutes to about 60 minutes.

Referring to FIG. 1 again, the organic semiconductor 154 is formed on the self-assembled layer 150 after surface-treating the self-assembled layer 150. The organic semiconductor 154 may be formed by a dry process such as chemical vapor deposition, or in a solution process such as spin coating, inkjet printing, and the like.

As described above, a particle or a multilayer attached on the surface of the self-assembled layer 150 may not only be efficiently removed, but the particle or the multilayer may also be removed over the entire area of the self-assembled layer 150 by applying a friction force in at least two directions on the surface of the self-assembled layer 150 after forming the self-assembled layer 150 but before forming the organic semiconductor 154. Accordingly, planarity of the self-assembled layer 150 is improved, and thus contact resistance between organic semiconductor and insulator may be reduced, and channel characteristics may be improved.

The organic thin film transistor may be applied to various display devices. The display device may be, for example a liquid crystal display (LCD), an organic light emitting diode (OLED) display, an electrophoretic display, and the like, but is not limited thereto.

According to example embodiments, a device for treating a surface of a thin film includes applying a friction force on the surface of the self-assembled layer.

The device of treating a surface of a thin film includes a rotator having a substantially perpendicular or parallel rotation axis with the ground, and the rotator is rotated on the surface of the thin film and applies a friction force in at least two directions on the surface of the thin film. Herein, cloth may be applied a region where the rotator contacts with the surface of the thin film. Referring to FIG. 6, the device of treating the surface of a thin film 400 includes the plate 200 having a substantially perpendicular rotation axis with the ground, and the plate 200 is rotated and thus may apply a friction force on the surface of the thin film and modify the surface of the thin film. On the bottom surface of the plate 200, cloth may be applied. The device of treating the surface of a thin film shown in FIG. 6 may simultaneously apply a friction force to a region having a predetermined area on the surface of the thin film. Referring to FIG. 7, the drum 300 having a substantially parallel rotation axis with the ground is rotated and may apply a friction on the surface of the thin film and thus modify the surface of the thin film. Herein, cloth may be applied on the surface of the drum 300. The thin film may be the aforementioned self-assembled layer.

Hereinafter, the present disclosure is illustrated in more detail with reference to examples. However, these are examples, and the present disclosure is not limited thereto.

### Manufacture of Organic Thin Film Transistor

### Example 1

An organic thin film transistor having an upper contact structure is manufactured by forming a self-assembled layer on an Si substrate doped with an SiO₂ layer and phosphorus (P) (SiO₂/P-doped Si), depositing an organic semiconductor thereon, and stacking a source and a drain electrode thereon.

Subsequently, the SiO₂/P-doped Si substrate is treated with O₂ plasma under a condition of 100 W and 60 seconds to activate a hydroxyl group. Then, octadecyltrimethoxysilane is dissolved in a trichloroethylene solvent to prepare a solution (an octadecyltrimethoxysilane-in-trichloroethylene solution), and the solution is spin-coated on the plasma-treated substrate. The spin coating is performed for 20 seconds at 3,000 rpm after wetting the solution on the substrate for 10 seconds. Subsequently, the substrate is exposed to NH₄OH vapor all night long to form a self-assembled layer.

Then, the self-assembled layer is dipped in a toluene solvent and cleaned with an ultrasonic wave for 3 minutes. Subsequently, the surface of the self-assembled layer is coated with a toluene solvent and then, rubbed with a clean room swab and mechanically cleaned.

### Example 2

An organic thin film transistor is manufactured according to the same method as Example 1 except for performing the ultrasonic wave cleaning by dipping a thin film in acetone and isopropylalcohol in order and then, performing the mechanical cleaning coating the acetone and the isopropylalcohol in order on the surface of the thin film.

### Comparative Example 1

An organic thin film transistor is manufactured according to the same method as Example 1 except for not coating the toluene solvent and not rubbing after the ultrasonic wave cleaning.

### Evaluation 1

Charge mobility of the organic thin film transistors according to Examples 1 and 2 and Comparative Example 1 is evaluated. The charge mobility is evaluated by using a semiconductor analyzer (4200-SCS, KEITHLEY Instrument, Inc.).

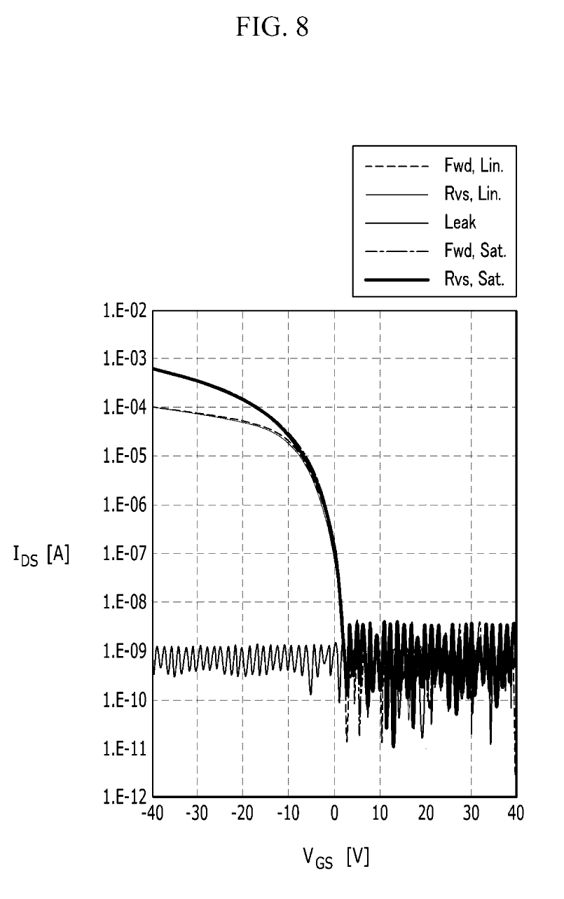

The results are provided in Table 1 and FIGS. 8 to 10.

TABLE 1

| | Charge mobility (cm²/Vs) |
|---|---|
| Example 1 | 8.43 |
| Example 2 | 6.52 |
| Comparative Example 1 | 3.07 |

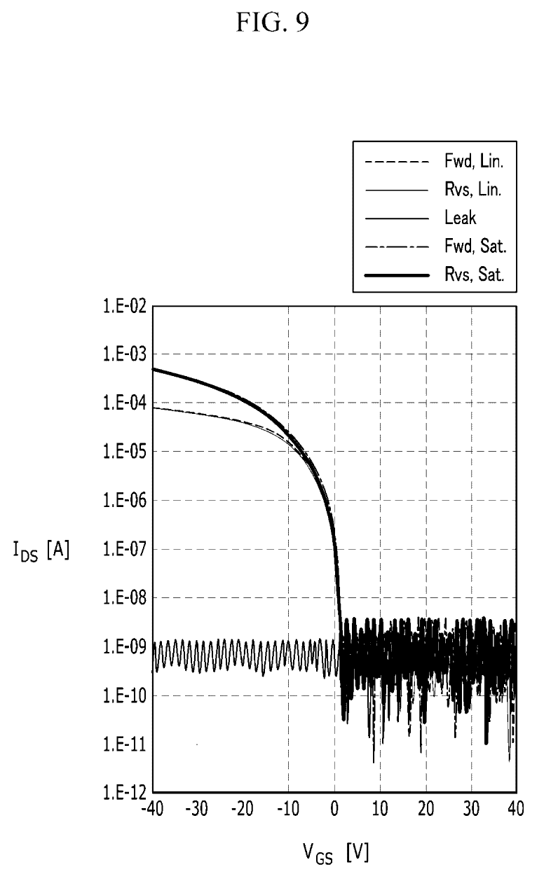

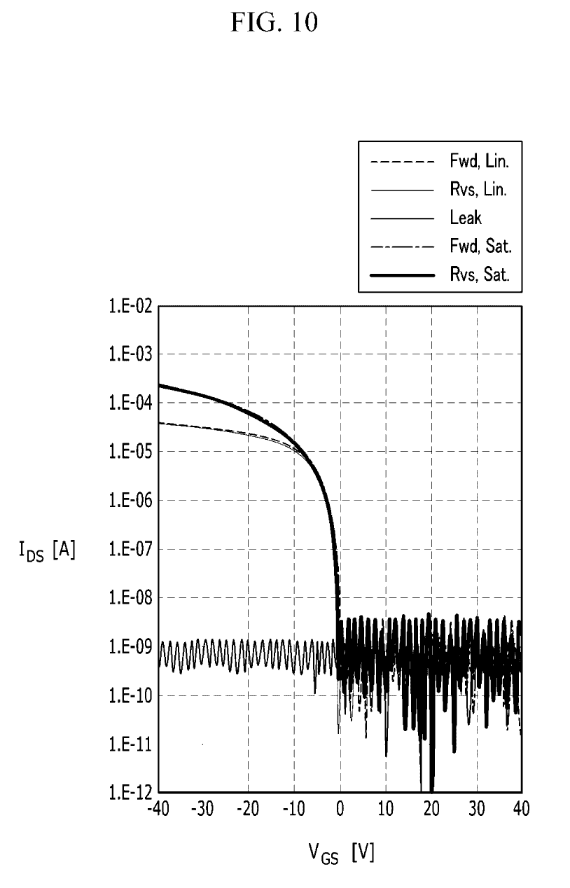

FIG. 8 is a graph showing charge mobility of the organic thin film transistor according to Example 1, FIG. 9 is a graph showing charge mobility of the organic thin film transistor according to Example 2, and FIG. 10 is a graph showing charge mobility of the organic thin film transistor according to Comparative Example 1.

Referring to Table 1 and FIGS. 8 to 10, the organic thin film transistors treated with the predetermined mechanical cleaning according to Examples 1 and 2 show improved charge mobility compared with the organic thin film transistor not treated with the mechanical cleaning according to Comparative Example 1.

### Evaluation 2

Self-assembled layer surface characteristics of the organic thin film transistors according to Examples 1 and 2 and Comparative Example 1 are examined through an atomic force microscope (AFM) image and surface roughness.

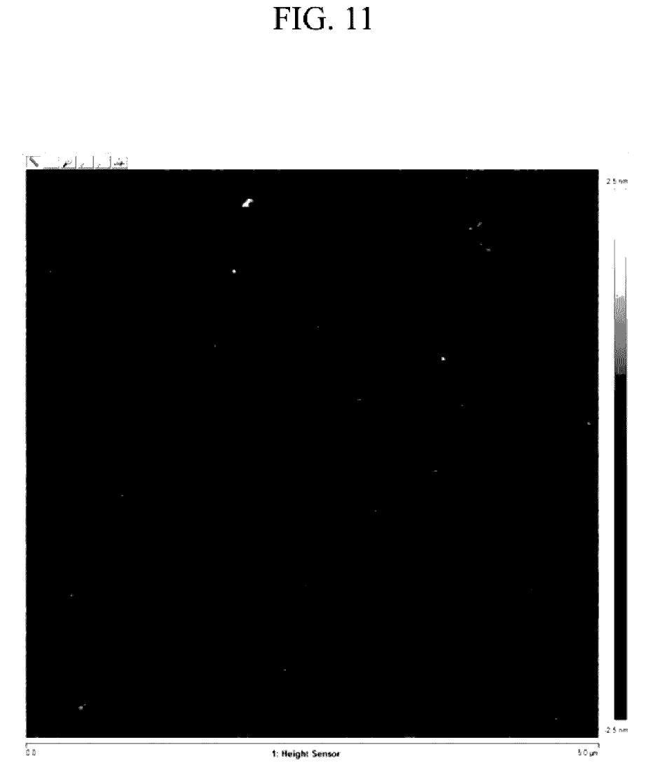

The results are provided in Table 2 and FIGS. 11 to 13.

TABLE 2

| | Surface roughness (nm) |
|---|---|
| Example 1 | less than or equal to 0.22 |
| Example 2 | less than or equal to 0.72 |
| Comparative Example 1 | less than or equal to 1.67 |

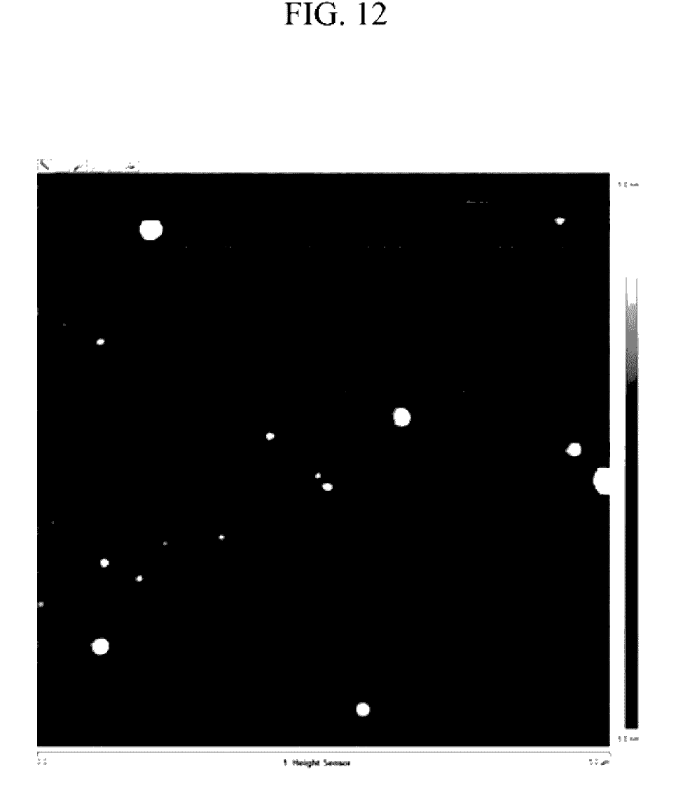

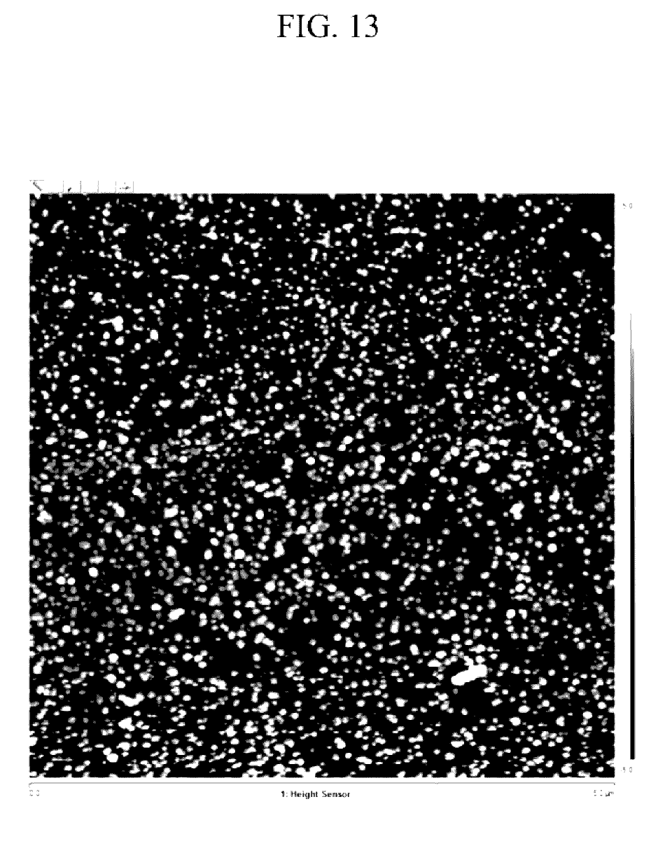

FIG. 11 shows an atomic force microscope (AFM) image showing the surface of the self-assembled layer according to Example 1, FIG. 12 shows an atomic force microscope (AFM) image showing the surface of the self-assembled layer according to Example 2, and FIG. 13 shows an atomic force microscope (AFM) image showing the surface of the self-assembled layer according to Comparative Example 1.

Referring to Table 2 and FIGS. 11 to 13, the organic thin film transistors treated with the predetermined mechanical cleaning according to Examples 1 and 2 show surface roughness of the self-assembled layer on an insulator and thus improved planarity compared with the organic thin film transistor not treated with the mechanical cleaning according to Comparative Example 1.

### Evaluation 3

Organic semiconductor arrangement of the organic thin film transistors according to Examples 1 and 2 and Comparative Example 1 is examined through an atomic force microscope (AFM) image.

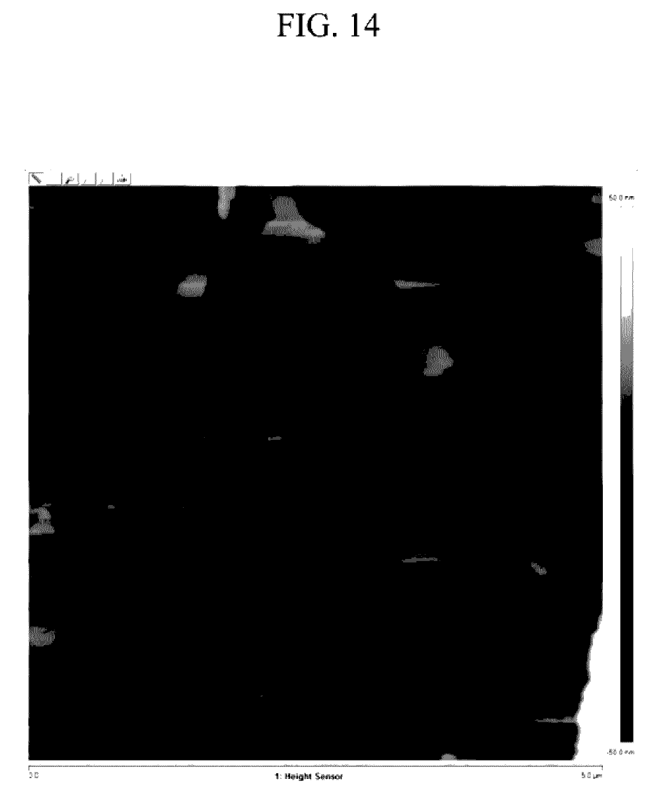

The results are provided in FIGS. 14 to 16.

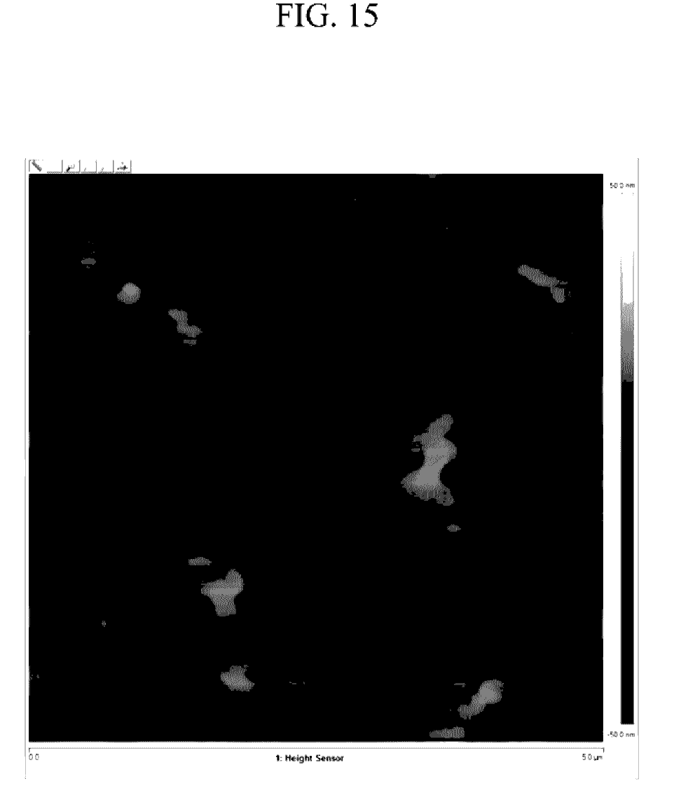

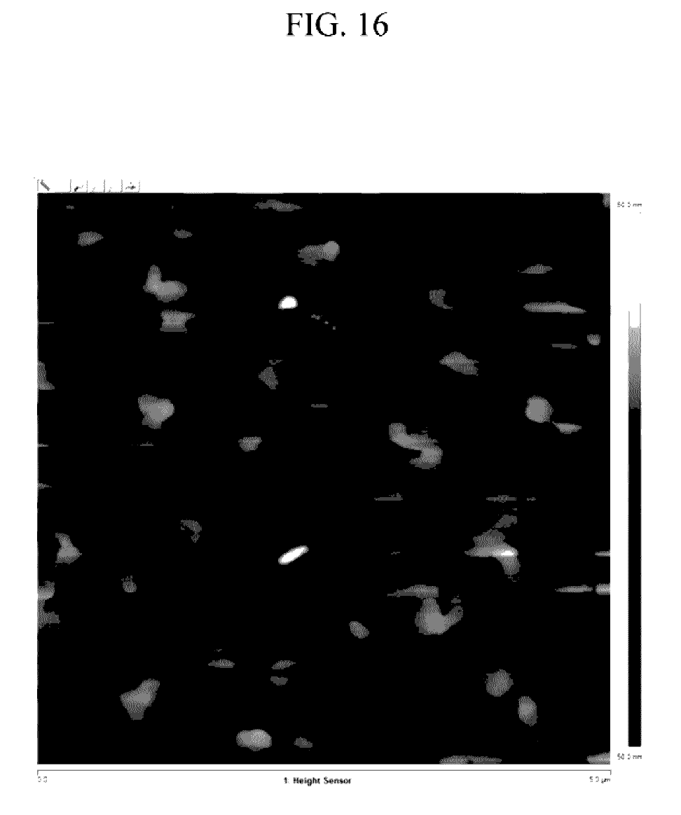

FIG. 14 shows an atomic force microscope (AFM) image showing the surface of the organic semiconductor according to Example 1, FIG. 15 shows an atomic force microscope (AFM) image showing the surface of the organic semiconductor according to Example 2, and FIG. 16 shows an atomic force microscope (AFM) image showing the surface of the organic semiconductor according to Comparative Example 1.

Referring to FIGS. 14 to 16, the organic thin film transistors treated with the predetermined mechanical cleaning according to Examples 1 and 2 show an improved organic semiconductor array compared with the organic semiconductor not treated with the mechanical cleaning according to Comparative Example 1.

While this disclosure has been described in connection with what is presently considered to be practical example embodiments, it is to be understood that the disclosure is not limited to the disclosed embodiments, but, on the contrary, is intended to cover various modifications and equivalent arrangements included within the spirit and scope of the appended claims.

What is claimed is:

1. A method of manufacturing an organic thin film transistor, the method comprising:
forming a gate electrode and a gate insulator on a substrate;
forming a self-assembled layer on the gate insulator from a self-assembled layer precursor;
applying friction to a surface of the self-assembled layer in at least two directions; and
forming an organic semiconductor on the self-assembled layer.

2. The method of claim 1, wherein the applying friction includes rubbing the surface of the self-assembled layer in the at least two directions.

3. The method of claim 1, wherein the applying friction includes rubbing a plate, a drum, or a combination thereof with the surface of the self-assembled layer.

4. The method of claim 3, wherein the applying friction applies the friction through rotation of a plate having a rotation axis substantially perpendicular to the substrate, rotation of a drum having a rotation axis substantially parallel to the substrate, or a combination thereof.

5. The method of claim 4, wherein the applying friction performs the rotation at a speed of less than or equal to about 2,000 rpm.

6. The method of claim 3, wherein at least one side of the plate and a surface of the drum has a region where cloth is applied.

7. The method of claim 3, wherein the applying friction applies the friction through movement of the substrate having the self-assembled layer in a horizontal direction.

8. The method of claim 1, wherein the applying friction simultaneously applies the friction to a region of the surface of the self-assembled layer.

9. The method of claim 1, wherein the forming a self-assembled layer forms the self-assembled layer by dipping, depositing, or spin coating.

10. The method of claim 1, wherein the forming a self-assembled layer forms the self-assembled layer directly on the gate insulator.

11. The method of claim 10, wherein the forming a self-assembled layer forms the self-assembled layer from the self-assembled layer precursor including a compound represented by Chemical Formula 1:
X—Y—Z [Chemical Formula 1]
wherein, in Chemical Formula 1,
X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein each of X₁, X₂, and X₃ are independently hydrogen, a substituted or unsubstituted C₁ to C₂₀ alkoxy group, a hydroxy group, or a halogen,
Y is —(CH₂)n-, wherein n is an integer of 0 to 30, —(CF₂)m-, wherein m is an integer of 0 to 30, or a combination thereof, and
Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, a halogen, thiol group, amine group, a nitro group or a combination thereof.

12. The method of claim 1, further comprising:
coating a liquid material on the surface of the self-assembled layer after the forming a self-assembled layer and prior to the applying friction.

13. The method of claim 12, wherein the coating coats hexane, cyclohexane, chloroform, anisole, mesitylene, xylene, toluene, ketone, ether, acetate, alcohol, amide, or a combination thereof.

14. The method of claim 12, further comprising:
treating the coated self-assembled layer with heat, a sound wave, acid, base, or a combination thereof after the forming a self-assembled layer and prior to the coating a liquid material.

15. The method of claim 14, wherein the treating treats the coated self-assembled layer with the sound wave while the coated self-assembled layer is dipped in a homogeneous or heterogeneous liquid material.

16. A device for treating a surface of a thin film comprising:
a rotator having a substantially perpendicular or parallel rotation axis with a ground surface, the rotator being configured to rotate on the surface of the thin film and apply friction in at least two directions thereon.

17. The device of claim 16, wherein
the rotator includes a plate having the substantially perpendicular rotation axis with the ground surface, a drum having the substantially parallel rotation axis with the ground surface, or a combination thereof, and
at least one side of the plate and a surface of the drum includes a region where cloth is applied.

18. The device of claim 16, wherein the thin film is a self-assembled layer.

19. An organic thin film transistor manufactured according to claim 1.

20. A display device comprising the organic thin film transistor of claim 19.
